(19) United States
(12) Patent Application Publication
(10) Pub. No.: US 2026/0173963 A1
(43) Pub. Date: Jun. 18, 2026

(54) FABRICATION METHOD FOR CHIPS WITH INTEGRATED MEMORY AND STRUCTURE THEREOF

(71) Applicant: HEFEI RELIANCE MEMORY LIMITED, Hefei (CN)

(72) Inventors: Chao-Yang CHEN, HEFEI (CN); Zhichao LU, SAN JOSE, CA (US); Liang ZHAO, SUNNYVALE, CA (US)

(21) Appl. No.: 19/225,835

(22) Filed: Jun. 2, 2025

Related U.S. Application Data
(63) Continuation of application No. PCT/CN2025/093095, filed on May 7, 2025.

(30) Foreign Application Priority Data
Dec. 17, 2024 (WO) PCT/CN2024/139909
Apr. 30, 2025 (CN) 202510565432.5

(51) Int. Cl. H01L 25/18; H01L 21/78; H01L 23/00; H01L 23/544; H10B 80/00

(52) U.S. Cl. CPC H10W 90/00; H10B 80/00; H10P 54/00; H10W 46/00; H10W 46/301; H10W 72/0198; H10W 80/312; H10W 80/327; H10W 90/792

(57) ABSTRACT

The embodiments of the present application provide a method of making a chip with integrated memory and structure thereof. The method of making a chip with integrated memory comprising: forming a plurality of base memory arrays at a first process node in a memory wafer using a memory photomask set, wherein each of the base memory arrays is surrounded by a plurality of scribe lines; forming a plurality of control chips at a second process node in a control wafer using a control photomask set, wherein the first process node is more advanced than the second process node, and each of the control chips is configured to control an operation of a corresponding memory chip comprising at least two base memory arrays; bonding the memory wafer with the control wafer together to form a bonded wafer, wherein each control chip is bonded with the corresponding memory chip; and cutting the bonded wafer through a subset of, but not all of the scribe lines to form a plurality of chips with integrated memory, wherein each chip with integrated memory comprises a scribe line that was not cut.

### CROSS-REFERENCE TO RELATED APPLICATIONS

This application is a continuation application of International Patent Application No. PCT/CN2025/093095, filed on May 7, 2025 and entitled “Fabrication Method for Chips with Integrated Memory and Structure Thereof”, which claims the benefit of and priority to International Patent Application No. PCT/CN2024/139909, filed on Dec. 17, 2024 and entitled “Resistive Random-Access Memory with Hybrid Bonding Integration”, and Chinese Patent Application No. 202510565432.5, filed on Apr. 30, 2025 and entitled “Fabrication Method for Chips with Integrated Memory and Structure Thereof”. The above-referenced applications are incorporated herein by reference in their entirety.

### TECHNICAL FIELD

The present invention relates to the field of semiconductor manufacturing, and more specifically to methods for fabricating chips with integrated memory and structure thereof.

### BACKGROUND

Resistive Random Access Memory (RRAM) is a type of non-volatile memory where the device's resistance can be switched between a low resistance state (LRS) and a high resistance state (HRS) by applying the appropriate voltage. The difference in resistance between LRS and HRS is used to store digital data as “0” and “1.”

In a typical RRAM memory IC, various peripheral circuits are formed alongside the RRAM array, and the same process node is used to manufacture both the memory array and the peripheral circuits. However, this approach is not optimal, as only the memory array requires the most advanced process technology to achieve high density, while the peripheral circuits could be manufactured with a more mature (lower cost) process node.

Furthermore, even in hybrid-bonded memory chips, accommodating varying memory capacity requirements is a challenge, as producing chips with different memory capacity necessitates a complete redesign and re-fabrication of the entire chip. Critically, when a chip including a different memory capacity is needed, the entire memory wafer, often fabricated using high-cost, advanced-node technology, must be redesigned and retaped-out, along with the control wafer. This leads to increased fabrication costs and extended development timelines.

### SUMMARY

To address the issues identified above, a two-chip solution with heterogeneous integration is provided in accordance with the embodiments of the present invention.

According to a first aspect of the present invention, a memory device is provided, including: a memory chip including a plurality of memory cells made at a first process node; and a control chip including a control circuit made at a second process node, wherein the first process node is more advanced than the second process node; wherein the control chip and the memory chip are bonded together to form the memory device via hybrid bonding integration technique, and the control circuit is configured to control an operation of the plurality of the memory cells in the memory chip.

In another embodiment of the present invention, the control circuit further includes a multiplexer configured to control a source line or a bit line for a memory cell.

In another embodiment of the present invention, the memory chip does not include a multiplexer configured to control a source line or a bit line for a memory cell.

In another embodiment of the present invention, the control circuit further includes a decoder configured to control a word line for a memory cell.

In another embodiment of the present invention, the memory chip does not include a decoder configured to control a word line for a memory cell.

In another embodiment of the present invention, the control circuit further includes a sense amplifier configured to amplify a signal for from a memory cell.

In another embodiment of the present invention, the control circuit further includes a charge pump configured to charge generate voltage required to program a memory cell.

In another embodiment of the present invention, the control chip further includes a processor.

In another embodiment of the present invention, the control chip further includes an analog circuit.

In another embodiment of the present invention, the control chip further includes a transmitter.

In another embodiment of the present invention, the control chip further includes a sensor.

In another embodiment of the present invention, a gate length of a transistor in the memory chip is smaller than a gate length of a transistor in the control chip.

In another embodiment of the present invention, the memory chip includes only one type of transistors, and the control chip includes a plurality type of transistors.

In another embodiment of the present invention, the memory chip includes only NMOS transistors.

In another embodiment of the present invention, the memory chip includes only PMOS transistors.

In another embodiment of the present invention, each memory cell includes a memory element formed above a substrate.

In another embodiment of the present invention, the memory element is selected from a group consisting of a Resistive Random Access Memory (RRAM); a Conductive-Bridge Random Access Memory (CBRAM); a Magnetic Random Access Memory (MRAM); a Ferroelectric Random Access Memory (FeRAM); and a Phase Change Random Access Memory (PCRAM).

In another embodiment of the present invention, each memory cell includes a resistive memory element formed above a substrate.

In another embodiment of the present invention, the memory cell includes: an access transistor formed on the substrate; a contact; a first metal layer; a bottom electrode; the resistive memory element; a first via; and a second metal layer, wherein the contact is disposed between a terminal of the access transistor and the first metal layer, the bottom electrode is disposed between the first metal layer and the resistive memory element, the first via is disposed between the resistive memory element and the second metal layer.

In another embodiment of the present invention, a top surface of the memory chip includes a plurality of first conductive pads and a first insulating region, a top surface of the control chip includes a plurality of second conductive pads and a second insulating region.

In another embodiment of the present invention, a first conductive pad is bonded to a second conductive pad, and the first insulating region is bonded to the second insulating region.

In another embodiment of the present invention, the plurality of first conductive pads are connected to a second metal layer in the memory chip by a plurality of memory chip vias, and a plurality of second conductive pads are connected to a second metal layer in the control chip by a plurality of control chip vias, wherein the plurality of memory chip vias include a same length.

In another embodiment of the present invention, prior to performing a write operation to a memory cell, the control circuit is configured to perform a read operation on the memory cell.

In another embodiment of the present invention, prior to performing a write operation to a memory cell, the control circuit is configured to compare data to be written with a result of a read operation.

In another embodiment of the present invention, the control circuit is configured to perform the write operation only if the data to be written does not match the result of the read operation.

According to a second aspect of the present invention, a method for performing a write operation in a memory device is provided, wherein the memory device includes a memory chip including a plurality of memory cells made at a first process node; and a control chip including a control circuit made at a second, wherein the first process node is more advanced than the second process node; wherein the control chip and the memory chip are bonded together to form the memory device, and the control circuit is configured to control an operation of the plurality of the memory cells in the memory chip; the method including: receiving an address of a memory cell in the memory chip and data to be written to the memory cell; by the control chip; performing a read operation on the memory cell; and performing a write operation on the memory cell after the read operation.

In another embodiment of the present invention, the method further including comparing the data to be written with a result of the read operation before performing the write operation on the memory cell.

In another embodiment of the present invention, performing a write operation on the memory cell after the read operation including performing a writing operation on the memory cell after the read operation only if the data to be written does not match the result of the read operation.

In the present invention, the memory chip is fabricated using an advanced process node, while the control chip is processed with a mature node. These two chips are then combined using 3D integration techniques, such as hybrid bonding, to form a fully functional memory chip.

In accordance with embodiments of the present invention, only the memory cells are fabricated using an advanced process node, while the peripheral circuits are fabricated using a mature node, which substantially reduces the cost of the memory chip, while increases the density of the memory cells.

According to a third aspect of the present invention, a method of making a chip with integrated memory is provided, including: forming a plurality of base memory arrays at a first process node in a memory wafer using a memory photomask set, wherein each of the base memory arrays is surrounded by a plurality of scribe lines; forming a plurality of control chips at a second process node in a control wafer using a control photomask set, wherein the first process node is more advanced than the second process node, and each of the control chips is configured to control an operation of a corresponding memory chip including at least two base memory arrays; bonding the memory wafer with the control wafer together to form a bonded wafer, wherein each control chip is bonded with the corresponding memory chip; and cutting the bonded wafer through a subset of, but not all of the scribe lines to form a plurality of chips with integrated memory, wherein each chip with integrated memory includes a scribe line that was not cut.

In some embodiments, each of the base memory arrays includes the same amount of memory capacity.

In some embodiments, at least some of the scribe lines include an alignment mark or an overlay mark, and the method further includes bonding the memory wafer with the control wafer in accordance with the alignment mark or the overlay mark.

In some embodiments, there is no dummy metal in a portion of the scribe line including the alignment mark or overlay mark.

In some embodiments, at least some of the scribe lines include a pattern configured to indicate whether the scribe line is to be cut, and the method further includes cutting the bonded wafer in accordance with the pattern.

In some embodiments, the control chip is selected from a group consisting of a microcontroller unit (MCU), a power management integrated circuit (PMIC), a display driver integrated circuit (DDIC), and an application-specific integrated circuit (ASIC).

In some embodiments, the control chip includes a control circuit, wherein the control circuit includes a multiplexer configured to control a source line or a bit line for a memory cell in the memory chip.

In some embodiments, the memory chip does not include a multiplexer configured to control a source line or a bit line for a memory cell in the memory chip.

In some embodiments, the memory chip does not include a decoder configured to control a word line for a memory cell in the memory chip.

In some embodiments, a gate length of a transistor in the memory chip is smaller than a gate length of a transistor in the control chip.

In some embodiments, the memory chip includes only one type of transistors, and the control chip includes a plurality of types of transistors.

In some embodiments, the memory chip includes only NMOS transistors.

In some embodiments, the memory chip includes only PMOS transistors.

In some embodiments, each memory cell includes a memory element formed above a substrate.

In some embodiments, the memory element is selected from a group consisting of: a Resistive Random Access Memory (RRAM); a Conductive-Bridge Random Access Memory (CBRAM); a Magnetic Random Access Memory (MRAM); a Ferroelectric Random Access Memory (FeRAM); and a Phase Change Random Access Memory (PCRAM).

In some embodiments, each memory cell includes a resistive memory element formed above a substrate.

In some embodiments, the memory cell includes: an access transistor formed on the substrate; a contact; a first metal layer; a bottom electrode; the resistive memory element; a first via; and a second metal layer, wherein the contact is disposed between a terminal of the access transistor and the first metal layer, the bottom electrode is disposed between the first metal layer and the resistive memory element, the first via is disposed between the resistive memory element and the second metal layer.

In some embodiments, a top surface of the memory chip includes a plurality of first conductive pads and a first insulating region, and a top surface of the control chip includes a plurality of second conductive pads and a second insulating region.

In some embodiments, a first conductive pad is bonded to a second conductive pad, and the first insulating region is bonded to the second insulating region.

In some embodiments, the plurality of first conductive pads are connected to a second metal layer in the memory chip by a plurality of memory chip vias, and a plurality of second conductive pads are connected to a second metal layer in the control chip by a plurality of control chip vias, wherein the plurality of memory chip vias include a same length.

In some embodiments, the method further includes forming a plurality of base memory arrays at the first process node in a second memory wafer using the memory photomask set, wherein each of the base memory arrays is surrounded by a plurality of second scribe lines; forming a plurality of second control chips at the second process node in a second control wafer using a second control photomask set different from the control photomask set, and each of the second control chips is configured to control an operation of a corresponding second memory chip including at least two base memory arrays; bonding the second memory wafer with the second control wafer together to form a second bonded wafer, wherein each second control chip is bonded with the corresponding second memory chip; and cutting the second bonded wafer through a subset of, but not all of the second scribe lines to form a plurality of second chips with integrated memory, wherein each second chip with integrated memory includes a second scribe line that was not cut.

In some embodiments, the memory chip and the second memory chip include different numbers of base memory arrays.

According to a fourth aspect of the present invention, a chip with integrated memory is provided, including: a memory chip formed at a first process node, wherein the memory chip includes at least two base memory arrays, wherein each of the base memory arrays is separated from another base memory array by at least a scribe line; and a control chip formed at a second process node, wherein the first process node is more advanced than the second process node, and the control chip is configured to control an operation of the memory chip, wherein a top surface of the memory chip includes a plurality of first conductive pads and a first insulating region, a top surface of the control chip includes a plurality of second conductive pads and a second insulating region, the first conductive pad is bonded to a second conductive pad, and the first insulating region is bonded to the second insulating region.

In some embodiments, each of the base memory arrays includes a same amount of memory capacity.

In accordance with embodiments of the present invention, the hybrid bonding technique provided above is further optimized to create chips with different memory capacities. Only the low-cost, mature-node control wafer requires re-engineering and retaping-out. In contrast, the high-cost, advanced-node memory wafer can be reused. As a result, this approach significantly reduces the fabrication time and costs associated with producing chips with different memory capacities.

### BRIEF DESCRIPTION OF THE DRAWINGS

The embodiments of the present invention may be more readily understood by referring to the following drawings.

FIG. 1A is a schematic diagram illustrating a memory device architecture commonly used in the industry.

FIG. 1B is a schematic diagram illustrating a novel memory device architecture with a hybrid bonding structure in accordance with embodiments of the present invention.

FIG. 2A is a schematic diagram illustrating a memory chip architecture within a hybrid bonding structure memory device commonly used in the industry.

FIG. 2B is a schematic diagram illustrating a novel Mux-free memory chip architecture in accordance with embodiments of the present invention.

FIG. 3 is a schematic diagram illustrating a novel customer defined memory device architecture with a hybrid bonding structure in accordance with embodiments of the present invention.

FIG. 4 is a schematic diagram illustrating a novel memory device architecture with a hybrid bonding structure in accordance with embodiments of the present invention.

FIG. 5A-FIG. 5B are schematic diagrams illustrating thickness and material of RRAM stack layers in the novel process for embedded RRAM in accordance with embodiments of the present invention.

FIG. 6 illustrates an example process flow for performing a write operation in a memory device in accordance with embodiments of the present invention.

FIG. 7 is a schematic diagram illustrating a memory device architecture commonly used in the industry.

FIG. 8 is a schematic diagram illustrating a memory device with integrated memory in accordance with embodiments of the present invention.

FIG. 9 is a schematic diagram illustrating a top view of chips with integrated memories that are formed by bonding memory chips with different control chips in accordance with embodiments of the present invention.

FIG. 10A and FIG. 10B are schematic diagrams illustrating a memory device with integrated memory in accordance with embodiments of the present invention.

FIG. 11 is a schematic diagram illustrating top views of memory devices with different memory capacities in accordance with embodiments of the present invention.

FIG. 12 is a schematic diagram illustrating a top view of a memory device in accordance with embodiments of the present invention.

FIG. 13 is a schematic diagram illustrating top views of memory wafers with alignment or overlay marks in accordance with embodiments of the present invention.

FIG. 14 is a schematic diagram illustrating a top view of a memory wafer with alignment mark in accordance with embodiments of the present invention.

FIG. 15 is a schematic diagram illustrating a top view of a memory device in accordance with embodiments of the present invention.

### DETAIL DESCRIPTION OF THE EMBODIMENTS

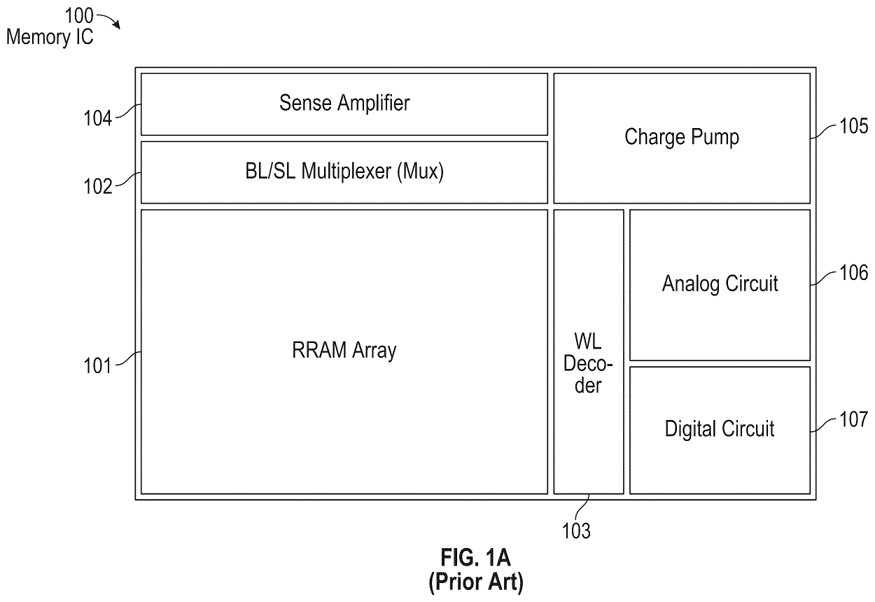

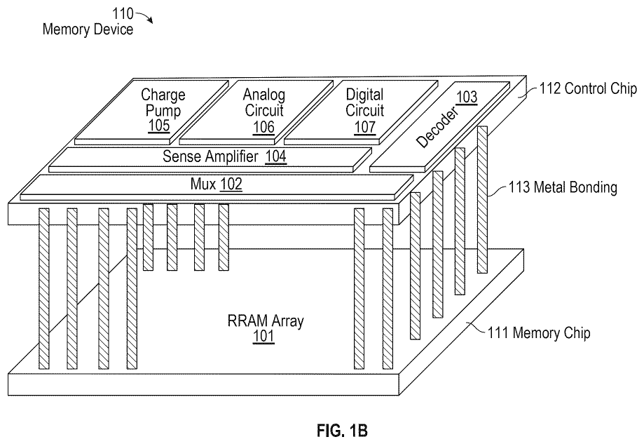

In a typical RRAM memory IC, beside the RRAM array, many peripheral circuits are required to support the functionality of RRAM. FIG. 1A is a schematic diagram illustrating a memory device architecture commonly used in the industry. As shown in FIG. 1A, a typical RRAM memory IC 100 may include a RRAM array 101, a bit line (BL)/source line (SL) multiplexer (Mux) 102, a word line (WL) decoder 103, a sense amplifier 104, a charge pump 105, an analog circuit 106, and a digital circuit 107. Thus, a lot of valuable areas are used to make the peripheral circuits, which limits the wafer areas that can be used to make RRAM memory cells. Furthermore, the most advanced process is required to make the memory cells to achieve high density, while the peripheral circuits can be processed with mature node, but it is not feasible to use different process node on the same wafer. In the present invention, two chips solution is proposed. RRAM array is fabricated with advanced node while other circuits are processed with mature node. These two chips are then combined with hybrid bonding technique. With this approach, the area on advanced process node wafer can be fully dedicated to fabricate high density memory cell, which would increase the competitiveness of the memory device. In addition, the advanced proceed used to fabricate high density memory cell can be further simplified when only one type of transistor with its regular and repetitive patterns is need to be fabricated, which in the end would significantly reduce process defects and increase chip yield.

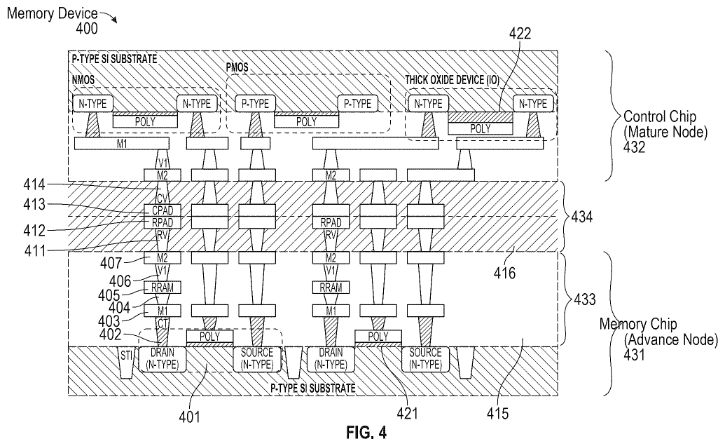

FIG. 1B is a schematic diagram illustrating a novel memory device architecture with a hybrid bonding structure in accordance with embodiments of the present invention. In the present invention, as shown in FIG. 1B, two chips solution is proposed. RRAM array is fabricated with advanced node while other circuits are processed with mature node. The memory device 110 may include a memory chip 111 and a control chip 112. The memory chip 111 includes a plurality of memory cells (denoted as “RRAM Array 101” in FIG. 1B) made at first process mode. The control chip 112 includes a control circuit made at a second process node, where the first process node is more advanced than the second process node. These two chips are bonded together with “hybrid bonding” technique (denoted as “Hybrid Bonding 113” in FIG. 1B) to form the memory device 110, and the control circuit is configured to control an operation of the plurality of the memory cells in the memory chip 111. The hybrid bonding, as will be elaborated later in descriptions of FIG. 4, comprises metal bonding and insulation bonding. FIG. 1B illustrates the metal bonding 113 but does not show the insulation bonding for the sake of visual clarity, which is also part of the structure.

Since the wafer used to create the memory chip 111 contains only memory cells and no control circuits, a higher number of memory cells can be fabricated on the same wafer. Thus, the utilization of the wafer is optimized.

As shown in FIG. 1B, the control chip 112 includes a Multiplexer (Mux) 102, a decoder 103, a sense amplifier 104, a charge pump 105, an analog circuit 106 and a digital circuit 107. The Mux 102 in the control chip 112 is configured to control a source line or a bit line for a memory cell in RRAM array 101, whereas the memory chip 111 does not include a multiplexer configured to control a source line or a bit line for a memory cell in RRAM array 101. The decoder 103 in the control chip 112 is configured to control a word line for a memory cell in RRAM array 101, whereas the memory chip 111 does not include a decoder configured to control a word line for a memory cell in RRAM array 101. The sense amplifier 104 in the control chip 112 is configured to amplify a signal from a memory cell in RRAM array 101, whereas the memory chip 111 does not include a sense amplifier configured to amplify a signal from a memory cell in RRAM array 101. The charge pump 105 in the control chip 112 is configured to generate voltage required to program a memory cell in RRAM array 101, whereas the memory chip 111 does not include a charge pump configured to generate voltage required to program a memory cell in RRAM array 101. Furthermore, the memory chip 111 does not include an analog circuit 106 or a digital circuit 107.

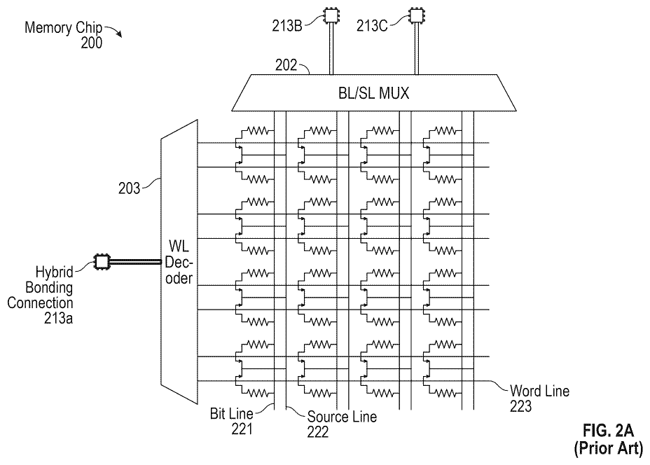

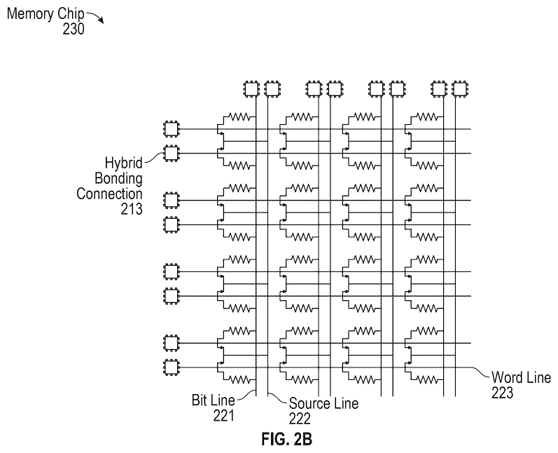

FIG. 2A is a schematic diagram illustrating a memory chip architecture within a hybrid bonding structure memory device commonly used in the industry. FIG. 2B is a schematic diagram illustrating a novel Mux-free memory chip architecture in accordance with embodiments of the present invention. As shown in FIG. 2A, prior art with hybrid bonding structure has bit line (BL)/source line (SL) mux 202 and word line (WL) decoder 203 on a memory chip 200 and has hybrid bonding connection 213a, 213b and 213c after BL/SL Mux 202 or WL decoder 203. Whereas memory chip 230 of the present invention may be Mux-free, as shown in FIG. 2B, since it only includes one type of transistor (either nmos or pmos) on RRAM chip. The hybrid bonding connections 213 connect to individual word lines 223, Bit Lines 221 and Source Lines 222 directly.

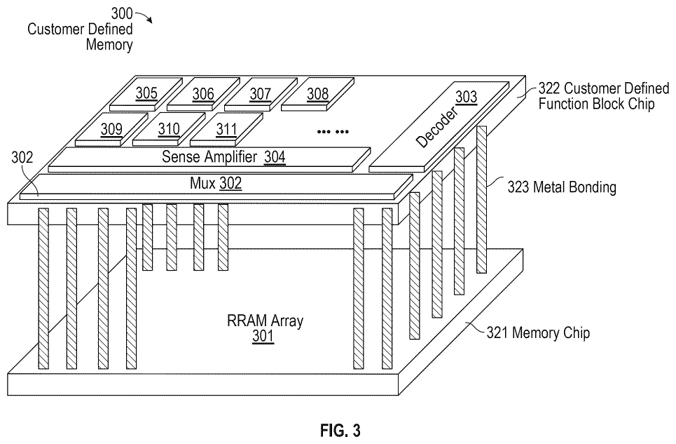

FIG. 3 is a schematic diagram illustrating a novel customer defined memory device architecture with a hybrid bonding structure in accordance with embodiments of the present invention. FIG. 3 shows a schematic diagram of a customer defined memory (CDM) 300, which may include a memory chip 321 and a customer defined function block chip 322 connected by hybrid bonding (for a better readability, FIG. 3 illustrates the metal bonding 323, but does not show the insulation bonding, which is also part of the hybrid bonding structure). The customer defined function block chip 322 may include a Mux 302, a decoder 303, a sense amplifier 304, a MCU 305, an analog circuit 306, a digital circuit 307, an ECC memory 308, a passive device 309, a sensor 310, a transmitter 311, and other customer defined blocks. The other customer defined function blocks may include other memory (e.g., SRAM), a power management IC, a mixed signal interface and an RF component. The analog circuit 306 may include an ADC, a DAC, a PLL, a V/I reference DC/DC, a power supply, or other analog circuits. The digital circuit 307 may include an MCU, a NPU, a GPU, a CPU or other digital circuits. The passive device 309 may include an inductor, a capacitor, a resistor, or other passive devices. The sensor 310 may include an image sensor, a CCD, a temperature sensor, a pressure sensor, a gas sensor, or other sensors. The mixed signal interface may include PCIe, Serdes, DDR, CXL, SPI/QPI, or other mixed signal interfaces. The RF component may include LNA, VCO, mixer and other RF components. The transmitter 311 may transmit communication signals. The memory chip 321 may include high density, high bandwidth and low power memory. In some embodiments, the memory chip 321 may include simple memory cell only.

The CDM 300 offers a comprehensive solution in the non-volatile memory (NVM) and non-volatile static random-access memory (NVSRAM) space. It is the most cost-effective option with a density range from approximately Mbit to multi-Gbit, featuring finer memory capacity granularity.

In addition to integrating customer-defined functional blocks, the CDM 300 delivers greater value within the same cost envelope. This flexibility allows for tailored, cost-effective solutions that meet specific customer requests while lowering the entry barriers for the adoption of RRAM and other emerging memory technologies, because only the control chip need to be taped out utilizing low-cost mature process while the advanced node memory chip can be re-used.

The CDM 300 extends its capabilities with multi-layer 3D integration for higher density memory and 2.5D interposer technology that provides high bandwidth. It is compatible with advanced memory interfaces, including SPI/QPI, DDR5, CXL, PCIe 6.0, and 112G SerDes.

Furthermore, the CDM 300 achieves SRAM-compatible speeds with random access, making it suitable for AI workloads in both edge and datacenter environments, enhancing performance while reducing power consumption.

The customer-defined memory CDM 300 in the present invention enhances device versatility by allowing customers to select specific features tailored to their needs. This approach enables memory to incorporate various control functionalities, allowing control circuits to be integrated directly with the memory cells, providing a more adaptable and feature-rich solution.

FIG. 4 is a schematic diagram illustrating a novel memory device architecture with a hybrid bonding structure in accordance with embodiments of the present invention. As shown in FIG. 4, memory devise 400 includes a memory chip 431 and a control chip 432. The memory chip 431 uses more advanced nodes than the control chip 432. The memory chip 431 includes a plurality of memory cells. The memory chip 431 only includes one type of transistor 410, which may either be nmos or pmos. On the other hand, the control chip 432 may contain many different types of transistors, which may be nmos, pmos, IO transistor, etc.

Since the memory chip 431 uses more advanced nodes than the control chip 432, the gate length 421 of access transistors 401 in the memory chip 431 is smaller than the gate length 422 of all the transistors in the control chip 432:

$${L}_{Gate \_ Memory} < {L}_{Gate \_ Control} .$$

The present invention uses only one type of transistor within the memory chip 431, significantly simplifying the fabrication process. By reducing the need for multiple types of transistors, this approach lowers the technical complexity, reduces number of photomasks, and minimizes the number of manufacturing steps required. This streamlined process not only decreases production difficulty but also enhances yield rates and reliability, ultimately leading to a reduction in overall manufacturing costs.

The memory chip 431 includes a p-type Si substrate, a BEOL metal and dielectric layer 433 and a hybrid bonding metal and dielectric layer 434. The p-type Si substrate includes the access transistor 401. The BEOL metal and dielectric layer 433 includes a contact 402, a first metal layer 403, a bottom electrode 404, a resistive memory element 405, a first via 406, a second metal layer 407 and insulation 415, wherein the contact 402 is disposed between a terminal of the access transistor 401 and the first metal layer 403, the bottom electrode 404 is disposed between the first metal layer 403 and the resistive memory element 405, the first via 406 is disposed between the resistive memory element 405 and the second metal layer 407. The BEOL metal and dielectric layer and its components, including the resistive memory element 405, are formed above the substrate.

The resistive memory element 405 is in BEOL of the memory chip 431.

The resistive memory element 405 may be replaced by a Resistive Random Access Memory (RRAM), a Conductive-Bridge Random Access Memory (CBRAM), a Magnetic Random Access Memory (MRAM), a Ferroelectric Random Access Memory (FeRAM), or a Phase Change Random Access Memory (PCRAM).

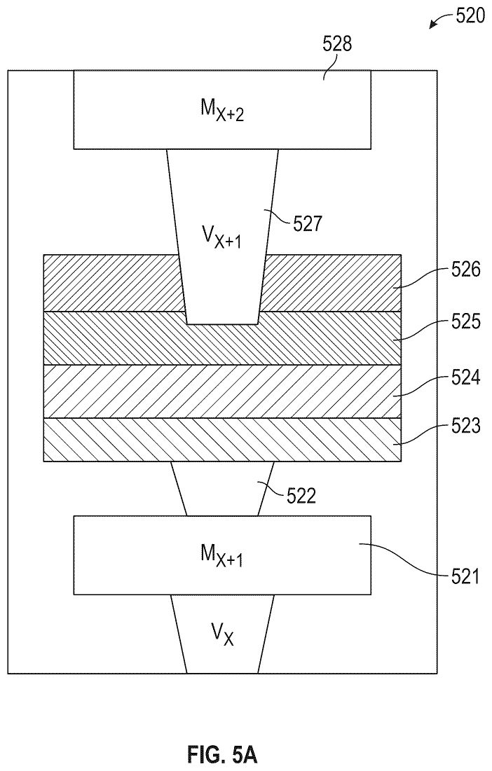

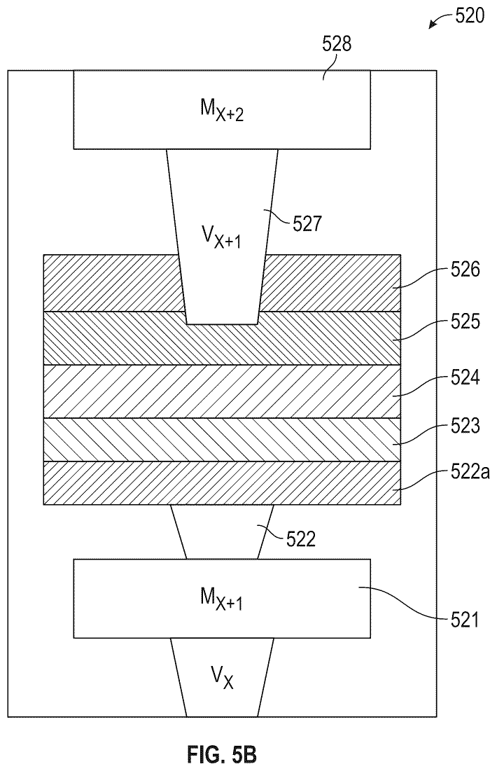

FIG. 5A-FIG. 5B are schematic diagrams illustrating thickness and material of RRAM stack layers in the novel process for embedded RRAM in accordance with embodiments of the present invention. The resistive memory element 405 may have two types of RRAM stack in the RRAM region 520: (a) RRAM with only one BE material, as shown in FIG. 5A; and (b) RRAM with two bottom electrodes, as shown in FIG. 5B. Referring to FIG. 5A, the thickness of the RRAM BE 522 may be 5 nm-500 nm and the material of the RRAM BE 522 may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials. The thickness of the dielectric layer 523 may be 0.1 nm-50 nm and the material of the dielectric layer 523 may be dielectric (SiO2, Ta2O5, TiO2, ZrO2, HfO2, Al2O3, etc.), including mixture and/or combination of these materials. The thickness of the capping layer 524 may be 1 nm-500 nm and the material of the capping layer 524 may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials. The thickness of the top electrode 525 may be 1 nm-500 nm and the material of the top electrode 525 may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials. On top of the RRAM stack, a hard mask layer 526 is also deposited. The material of the hard mask layer 526 may be SiN. In this example, via Vₓ₊₁ 527 and metal layer Mₓ₊₂ 528 is used where via Vₓ₊₁ 527 is etched through the hard mask 526 and connects to the RRAM top electrode 525.

Referring to FIG. 5B, there is a second RRAM BE 522a deposited between the dielectric layer 523 and the first RRAM BE 522. The thickness of the second RRAM BE 522a may be 1 nm 500 nm and the material of the second RRAM BE 522a may be metals (Ti, Hf, Ta, Ru, Ir, Pt, etc.), metal oxide (TiOx, TaOx, HfOx, etc.), metal nitrides (TiN, TaN, AlN, etc.), metal oxynitride (TiON, TaON, AlON, etc.), or other suitable conductive materials.

As shown in FIG. 4, the memory chip portion of the hybrid bonding metal and dielectric layer 434 includes memory chip vias 411, memory chip pads 412 and insulation 416; the control chip portion of the hybrid bonding metal and dielectric layer 434 includes control chip vias 414, control chip pads 413 and insulation 416. A top surface of a memory chip 431 includes a plurality of first conductive pads, which are the memory chip pads 412, and a first insulation region; a top surface of a control chip 432 includes a plurality of second conductive pads, which are the control chip pads 413, and a second insulation region. In a hybrid bonding process, the memory chip pads 412 are bonded to the control chip pads 413, and the first insulating region is bonded to the second insulating region. The plurality of the memory chip pads 412 are connected to metal layers 407 in the memory chip 431 by a plurality of vias, which are the memory chip vias 411 and a plurality of second conductive pads 413 are connected to metal layers in the control chip 432 by a plurality of second vias, which are the control chip vias 414, wherein the plurality of memory chip vias 411 comprise a same length that they do not form a staircase shape.

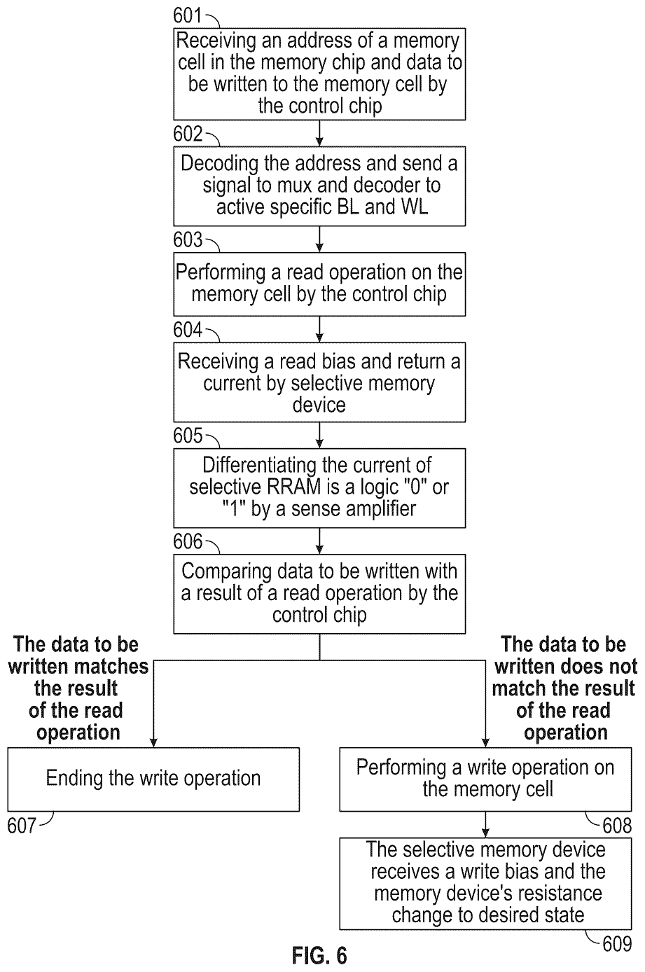

FIG. 6 illustrates an example process flow for performing a write operation in a memory device in accordance with embodiments of the present invention. The following describes a method for performing a write operation in a memory device, as referred to FIG. 6. The method shown in FIG. 6 includes the following control flow steps:
S601: receiving an address of a memory cell in the memory chip and data to be written to the memory cell by the control chip;
S602: decoding the address and send a signal to mux and decoder to active specific BL and WL;
S603: performing a read operation on the memory cell by the control chip;
S604: receiving a read bias and return a current by selective memory device;
S605: differentiating the current of selective RRAM is a logic “0” or “1” by a sense amplifier;
S606: comparing data to be written with a result of a read operation by the control chip;
S607: if the data to be written matches the result of the read operation, ending the write operation;
S608: if the data to be written does not match the result of the read operation, performing a write operation on the memory cell;
S609: the selective memory device receives a write bias and the memory device's resistance change to desired state.

The memory device includes a memory chip comprising a plurality of memory cells made at a first process node; and a control chip comprising a control circuit made at a second process node, wherein the first process node is more advanced than the second process node; wherein the control chip and the memory chip are bonded together to form the memory device, and the control circuit is configured to control an operation of the plurality of the memory cells in the memory chip.

In S601, S602, S605, S606 and S607, a signal is sent within the same chip (either within the control chip or within the memory chip).

In S603, S604 S608 and S609, a signal is sent across the control chip and the memory chip.

Differ from prior art, where all bits are programmed regardless of the value to be stored, the present invention introduces a more efficient approach. Before a write operation, the control chip performs a read operation on the memory cell to determine whether the bit needs programming. If the stored value matches the desired data, no programming is performed. Additionally, the present invention eliminates the need for a refresh operation.

This selective write process of the present invention reduces unnecessary write cycles, which is particularly beneficial for RRAM, as it has a limited write endurance. By reducing the number of write operations, our approach extends the lifespan of both the RRAM and the entire device, enhancing durability and reliability.

In some embodiments, the hybrid bonding technique provided above is further optimized for enhanced applications. Specifically, a memory wafer and a control wafer are connected using hybrid bonding to form fully functional memory devices. The memory wafer includes thousands of grids of uniform-sized memory arrays. To create a chip with integrated memory having a different memory capacity, only the control wafer needs to be redesigned to match a selected number of memory arrays. Critically, the memory wafer remains unmodified across different configurations—only the control wafer design and the dicing process are adjusted to combine specific tiles of memory arrays during wafer cutting. This approach significantly reduces fabrication and time costs for chips with varying memory capacity requirements, as only the low-cost, mature-node control wafer needs to be re-engineered and retaped-out, while the high-cost, advanced-node memory wafer can be reused.

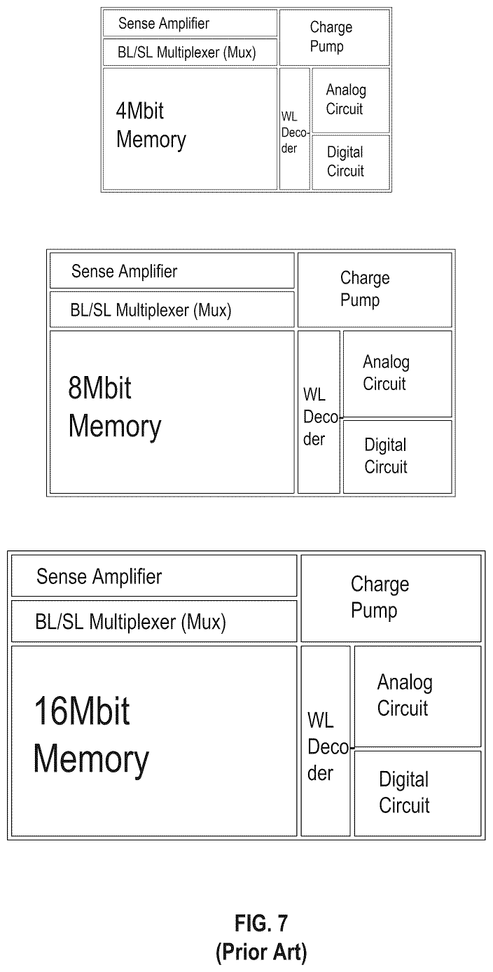

FIG. 7 is a schematic diagram illustrating a memory device architecture commonly used in the industry. As shown in FIG. 7, in conventional memory device designs, various peripheral circuits are formed alongside the memory array. Although the peripheral circuits can be manufactured using a mature process node, the memory cells require the most advanced process to achieve high growing market demand for smaller, more powerful electronic devices with large-scale data storage capabilities. Since it is not feasible to use different process nodes on the same wafer, the advanced process node must be used for both the memory array and the peripheral circuits. Generally, a single photomask set is used to fabricate memory devices with a fixed memory capacity (e.g., 4 Mbit). To produce memory devices with different memory capacities (e.g., 8 Mbit, 16 Mbit, etc.), entirely new photomask sets must be designed. This approach is costly because completely new photomask sets are required for the expensive advanced process nodes when developing new memory devices with different memory capacities.

In the embodiments mentioned above, a memory device based on a hybrid bonding approach was proposed, connecting an advanced-node memory chip with a mature-node control chip. In this invention, the benefits of the hybrid bonding technique are further leveraged. To produce memory devices with different memory capacities, only the mature-node control chip needs to be re-designed and re-taped out with a new photomask set, while the photomask set for the advanced-node memory wafer can be reused for various memory capacities.

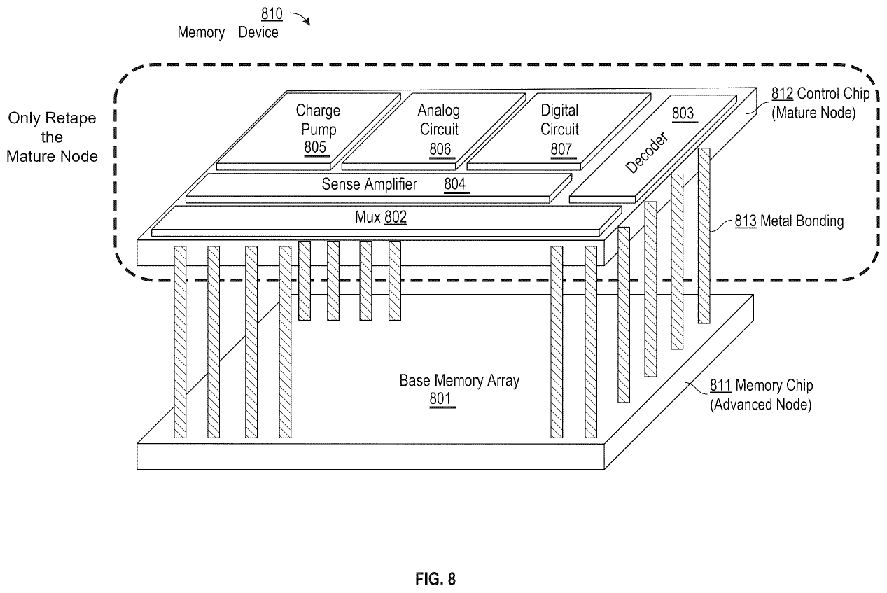

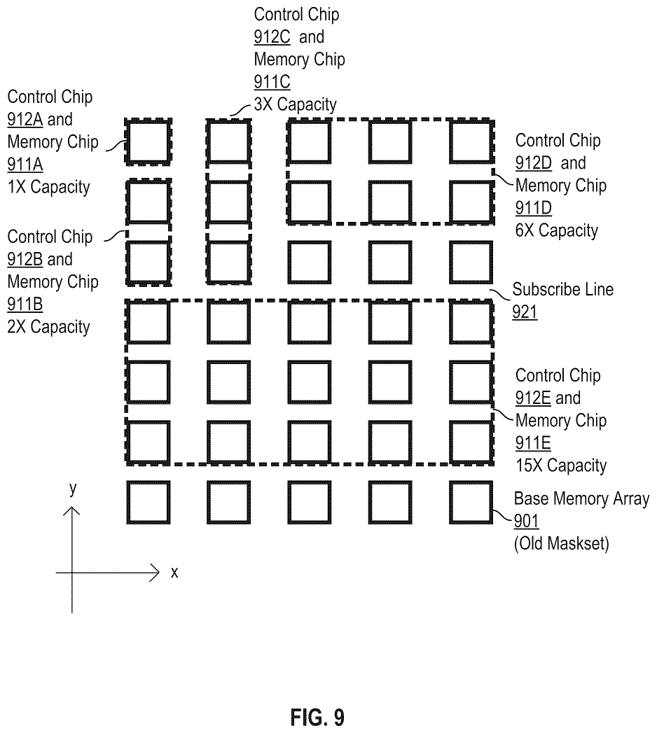

FIG. 8 is a schematic diagram illustrating a memory device with integrated memory in accordance with embodiments of the present invention. As shown in FIG. 8, the memory device 810 includes a memory chip 811 and a control chip 812. The memory chip 811 is fabricated on a memory wafer at a first, more advanced process node, utilizing a memory photomask set. The memory chip 811 may be conceptually similar to any of the memory chips 911A-911E shown in FIG. 9. The memory chip 811 includes one or more, but preferably at least two, of identical base memory arrays 801. Notably, FIG. 8 does not explicitly illustrate scribe lines separating base memory arrays, nor does it depict the grid structure of the memory arrays 801, which will be depicted and described in FIG. 9 and later paragraphs related to FIG. 9.

The control chip 812, in contrast, is fabricated on a separate control wafer at a second process node, which is less advanced than the first process node used for the memory chip. The control chip 812 may be conceptually similar to any of the control chips 912A-912E shown in FIG. 9. The control chip 812 is fabricated using a control photomask set. Each control chip 812 is specifically designed to manage operations of its corresponding memory chip 811.

To create a fully functional memory device 810, each control chip 812 is bonded to its corresponding memory chip 811 using a hybrid bonding technique, or a similar bonding approach. This hybrid bonding, which is described in further detail in relation to FIG. 4, involves both metal-to-metal bonding (illustrated as 813 in FIG. 8) and insulator-to-insulator bonding. While the insulator bonding is not explicitly shown in FIG. 8 for clarity, it is a crucial part of the structural integrity of the bonded device.

As shown in FIG. 8, the control chip 812 incorporates several key circuit components, including a Multiplexer (Mux) 802, a decoder 803, a sense amplifier 804, a charge pump 805, an analog circuit 806, and a digital circuit 807. The Mux 802 within the control chip 812 is configured to select and control either the source line or the bit line for accessing individual memory cells within the base memory array 801. The memory chip 811 itself does not contain a multiplexer. Similarly, the decoder 803 in the control chip 812 controls the word lines used to access memory cells in the base memory array 801, and the memory chip 811 does not include its own word line decoder. The sense amplifier 804 on the control chip 812 amplifies the weak signals read from the memory cells in the base memory array 801, while the memory chip 811 does not have a dedicated sense amplifier. The charge pump 805, also located on the control chip 812, generates the necessary higher voltages required for programming (writing data to) the memory cells in the base memory array 801. The memory chip 811, designed for high density and fabricated at the more advanced node, is kept simpler and does not include a charge pump. Furthermore, the memory chip 811 does not include the analog circuit 806 or digital circuit 807, concentrating all control and peripheral circuitry on the control chip 812. This strategic partitioning allows for independent optimization, maximizing memory density on the advanced-node memory chip while implementing the necessary control and peripheral functions cost-effectively on the mature-node control chip.

In some embodiments, a method of manufacturing a chip with integrated memory is provided. This method includes forming a plurality of base memory arrays 801 on a memory wafer. These arrays are fabricated at a first, more advanced process node using a memory photomask set. Each base memory array 801 is surrounded by scribe lines. This method further includes forming a plurality of control chips 812 on a separate control wafer at a second, less advanced process node, using a control photomask set. Each control chip 812 is designed to control the operation of a corresponding memory chip 811, which includes one or more base memory arrays 801. Preferably, the memory chip 811 includes at least two of the base memory arrays 801. The memory wafer and the control wafer are then bonded together, aligning and joining each control chip 812 to its corresponding memory chip 811, forming a bonded wafer. Finally, the bonded wafer is diced by cutting through some, but not all, of the scribe lines. This selective cutting creates individual chips with integrated memory. Each resulting chip will include at least one scribe line that was not cut, indicating the boundaries of the original base memory arrays to separate one from another.

FIG. 9 is a schematic diagram illustrating a top view of chips with integrated memories that are formed by bonding memory chips with different control chips in accordance with embodiments of the present invention. As shown in FIG. 9, various memory chips 911A, 911B, 911C and 911E include one or more identical base memory arrays 901. These base memory arrays 901 are arranged in a grid pattern and are physically separated from each other by a series of scribe lines 921. These scribe lines 921 extend in both the x and y directions, effectively isolating each base memory array from the others.

FIG. 9 illustrates that different control chips 912A, 912B, 912C, and 912E, fabricated on a separate control wafer (not explicitly shown in FIG. 9 for clarity), can be designed to bond with and control different groupings of the base memory arrays 901 on the memory wafer. Furthermore, it is noted that these different control chips (912A-912E) can be designed on the same control wafer or across different control wafers; for instance, a single control wafer could be patterned using one control photomask set to produce multiple instance of one type of control chip (e.g., 912A), or it could be patterned using a plurality of control photomask sets (or a single, more complex set) to produce two or more different types of control chips (e.g., both 912A and 912B) repeated across the wafer. This allows for a plurality of final memory device configurations. For instance, control chip 912A might correspond to memory chip 911A controlling a smaller set of base memory arrays 901, while control chip 912E corresponds to memory chip 911E controlling a larger set of base memory arrays 901. This highlights the flexibility where a plurality of distinct control chip designs (912A-912E) can be bonded with different subsets of base memory arrays 901 originating from the same memory wafer design.

As shown in FIG. 9, the final memory capacity of the memory device is determined after the bonding and dicing process. This is achieved by redesigning the control photomask sets required for mature-node control wafers and by selectively cutting through specific scribe lines 921 during the dicing process. This approach allows for the creation of chips with varying memory capacities utilizing the same memory wafer. Critically, the memory wafer, which is fabricated at the more advanced and expensive process node, remains unchanged regardless of the final chip configuration. This significantly reduces the costs associated with re-designing and re-fabricating (re-tapeout) the advanced-node memory wafers for different memory capacities.

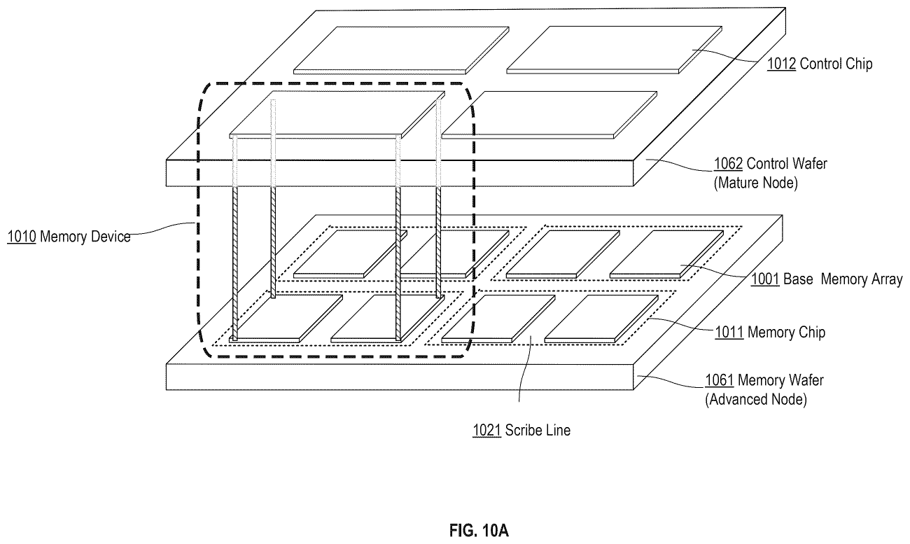

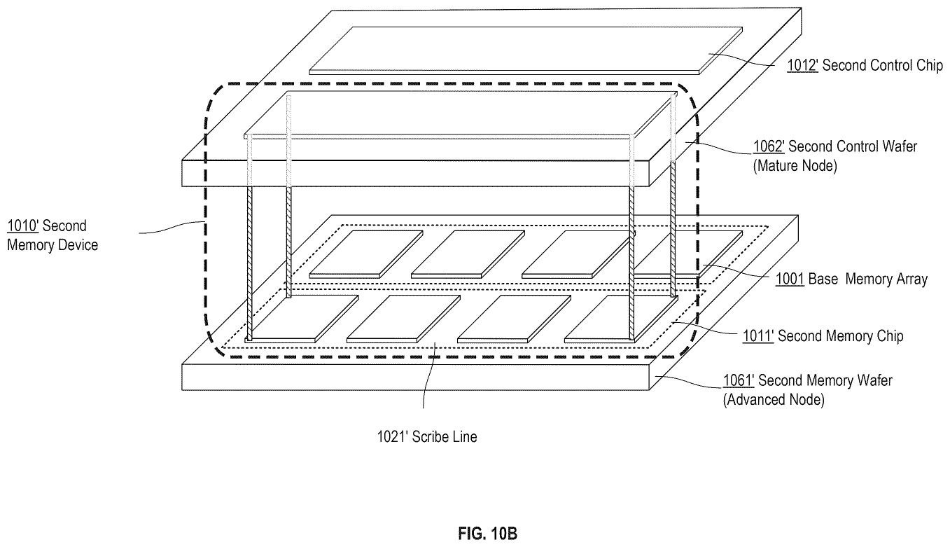

FIGS. 10A and 10B are schematic diagrams illustrating memory devices with integrated memory in accordance with embodiments of the present invention. As shown in FIG. 10A, a plurality of base memory arrays 1001 are formed on a first memory wafer 1061 at a first, more advanced process node using a memory photomask set. Each base memory array 1001 is surrounded by scribe lines 1021. Control chips 1012 are formed on a first control wafer 1062 at a second, less advanced process node, using a control photomask set. Each control chip 1012 is configured to control a corresponding memory chip 1011, which includes two base memory arrays 1001. The first memory wafer and first control wafer are bonded, aligning each control chip 1012 with its corresponding memory chip 1011. The bonded wafer is then diced by cutting through some, but not all, of the scribe lines 1021, creating a plurality of chips (denoted as memory device 1010 in FIG. 10A). Each resulting chip contains at least one uncut scribe line 1021. FIG. 10B illustrates a second set of memory devices. As shown in FIG. 10B, a plurality of base memory arrays 1001 are formed on a second memory wafer 1061′, using the same memory photomask set as before, at the same first process node. However, the resulting memory chips 1011′ on this second wafer 1061′ will include a different number of base memory arrays 1001 compared to the memory chips 1011 on the first wafer 1061. These base memory arrays are also surrounded by second scribe lines 1021′. A plurality of second control chips 1012′ are formed on a second control wafer 1062′, using a different control photomask set from the first control wafer, at the second process node. Each of the second control chips 1012′ is designed to control a corresponding second memory chip 1011′, which contains four base memory arrays 1001. The second memory wafer and second control wafer are then bonded, aligning each second control chip 1012′ with its corresponding second memory chip 1011′. This second bonded wafer is then diced by cutting through some, but not all, of the second scribe lines 1021′, creating a plurality of second memory device 1010′ with integrated memory. Each of these second memory devices 1010′ includes at least one uncut second scribe line 1021′. More generally, embodiments of the invention allow for the creation of a variety of memory devices by integrating different numbers of base memory arrays (e.g., one, two, three, four, or N arrays, where N is a positive integer) from a memory wafer produced using the first process node and a memory photomask set, with corresponding control chips designed specifically for that number of base arrays and fabricated using the second process node. This process demonstrates the flexibility of creating different memory devices using the same memory wafer design.

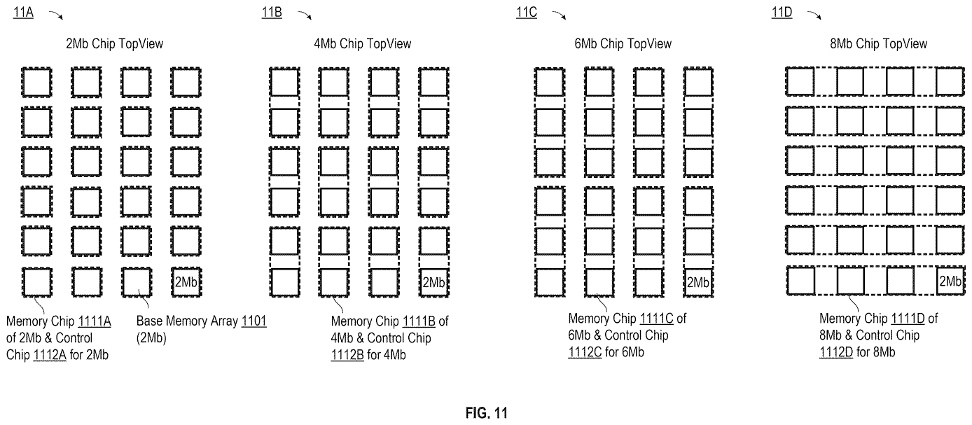

FIG. 11 is a schematic diagram illustrating top views of memory devices with different memory capacities in accordance with embodiments of the present invention. The total memory capacity of various memory devices is a multiple of the capacity of an individual base memory array. For example, as illustrated in FIG. 11, assuming each base memory array 1101 has a capacity of 2 Mbit, various memory devices configuration can be created using the fabrication method described above. For example, a 2 Mbit memory device 11A can be fabricated by bonding a memory chip 1111A, which comprises a single base memory array 1101, to a corresponding control chip 1112A. A 4 Mbit memory device 11B can be fabricated by bonding a memory chip 1111B, which comprises two base memory arrays 1101, to a corresponding control chip 1112B. A 6 Mbit memory device 11C can be fabricated by bonding a memory chip 1111C, which comprises three base memory arrays 1101, to a corresponding control chip 1112C. An 8 Mbit memory device 11D can be fabricated by bonding a memory chip 1111D, which comprises four base memory arrays 1101, to a corresponding control chip 1112D. Similar processes can be applied to obtain memory devices with capacities increasing in 2 Mbit increments (e.g., 10 Mb, 12 Mb, etc.). This modular approach allows for the production of memory devices with capacities that may not be readily available in the market, such as 6 Mbit or 10 Mbit chips, thereby opening up new market opportunities.

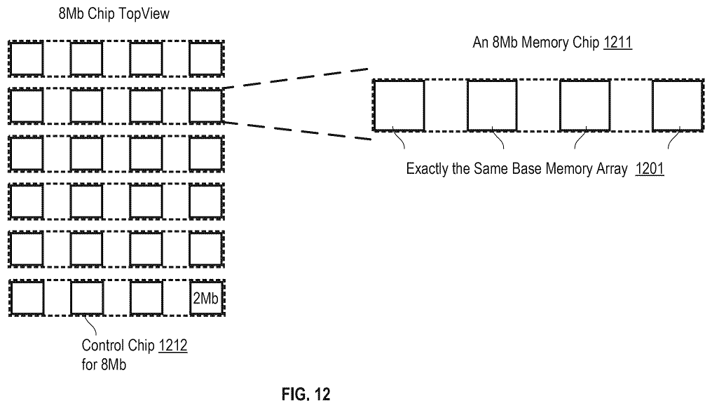

Each of the memory chips 1111A, 1111B, 1111C, and 1111D in FIG. 11 is constructed from one or more identical base memory arrays 1101. Each base memory array 1101 within a given memory chip has the exact same memory capacity. It should be noted that the capacity of each base memory array may vary based on actual requirements and is not limited to a fixed value. As a result, the memory capacity of memory devices fabricated using the method described above may differ accordingly. FIG. 12 is a schematic diagram illustrating a top view of a memory device in accordance with embodiments of the present invention. As shown in FIG. 12, an 8 Mbit memory chip 1211, which is composed of four identical 2 Mbit base memory arrays 1201, is bonded to a corresponding control chip 1212. This uniformity simplifies design and manufacturing.

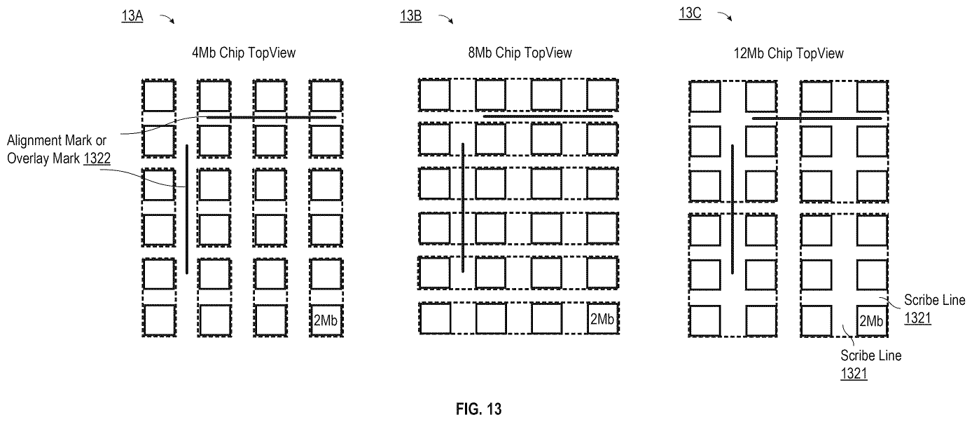

During the fabrication of the memory devices described above, precise alignment is essential for bonding the control wafer and memory wafer. FIG. 13 is a schematic diagram illustrating top views of memory wafers with alignment or overlay marks in accordance with embodiments of the present invention. As shown in FIG. 13, at least some of the scribe lines 1321 incorporate alignment marks or overlay marks 1322. These marks ensure precise alignment and bonding between the memory and the control wafers. The alignment marks ensure that the conductive pads on the memory and control chips are correctly positioned for bonding. Additionally, at least some of the scribe lines 1321 may include a pattern or indicator that designates whether that particular scribe line is intended to be cut during the dicing process. This allows for pre-planned separation of the bonded wafer into chips of the desired size.

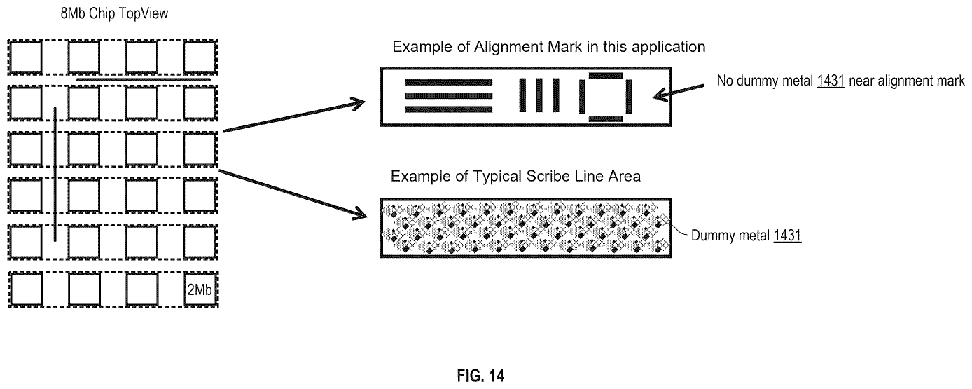

FIG. 14 is a schematic diagram illustrating a top view of a memory wafer with alignment mark in accordance with embodiments of the present invention. As shown in FIG. 14, the scribe line area is intentionally kept free of dummy metal structures 1431. This is in contrast to typical scribe line designs, which are often filled with dummy metal structures 1431, and dummy metal structures 1431 in different shapes represent various metal layers. The absence of metal dummies in the scribe line area is crucial for achieving accurate wafer alignment during the bonding process. Metal dummies can interfere with optical alignment systems, so their removal ensures optimal alignment accuracy.

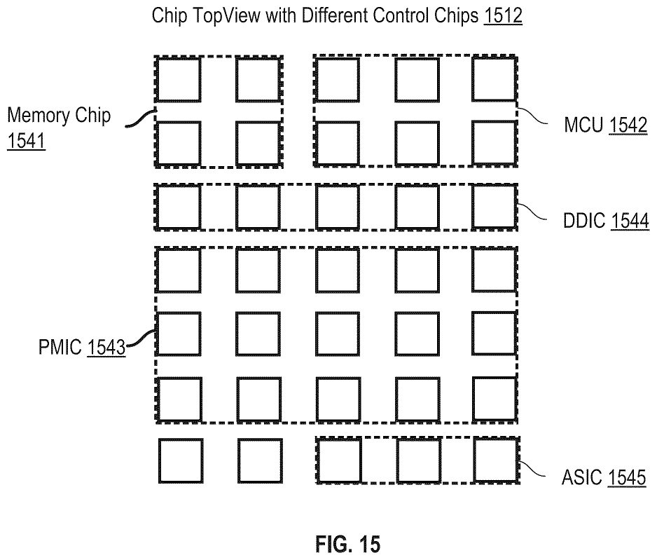

Chips with integrated memory can be fabricated to serve various purposes based on specific requirements. FIG. 15 is a schematic diagram illustrating a top view of a memory device in accordance with embodiments of the present invention. As shown in FIG. 15, the control chip 1512 may be one or more memory chip 1541 or any other chip that requires memory functionality including but not limited to a microcontroller unit (MCU) 1542, a power management integrated circuit (PMIC) 1543, a display driver integrated circuit (DDIC 1544), an application-specific integrated circuit (ASIC) 1545 and others.

In some embodiments, a chip with integrated memory is provided. This chip includes a memory chip fabricated at a first, more advanced process node. The memory chip includes at least two base memory arrays, and each base memory array is separated from the others by at least one scribe line. The chip also includes a control chip, fabricated at a second, less advanced process node. The control chip is designed to manage the operation of the memory chip. The top surface of the memory chip features a plurality of first conductive pads and a first insulating region. Similarly, the top surface of the control chip has a plurality of second conductive pads and a second insulating region. The bonding process joins the first conductive pads of the memory chip to the corresponding second conductive pads of the control chip. Simultaneously, the first insulating region of the memory chip is bonded to the second insulating region of the control chip. This hybrid bonding creates a robust and reliable connection between the two chips.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. Other embodiments may have layers in different orders, additional layers or fewer layers than the illustrated embodiments.

Various operations are described as multiple discrete operations, in turn, in a manner that is most helpful in understanding the present invention, however, the order of description should not be construed to imply that these operations are necessarily order dependent. In particular, these operations need not be performed in the order of presentation.

The terms “over,” “above” “under,” “between,” and “on” as used herein refer to a relative position of one material layer or component with respect to other layers or components. For example, one layer deposited above or over or under another layer may be directly in contact with the other layer or may have one or more intervening layers. Moreover, one layer deposited between two layers may be directly in contact with the two layers or may have one or more intervening layers. In contrast, a first layer “on” a second layer is in direct contact with that second layer. Similarly, unless explicitly stated otherwise, one feature deposited between two features may be in direct contact with the adjacent features or may have one or more intervening layers.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims may generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. The terms “first,” “second,” “third,” “fourth,” etc. as used herein are meant as labels to distinguish among different elements and may not necessarily have an ordinal meaning according to their numerical designation.

What is claimed is:

1. A method of making a chip with integrated memory, comprising:
forming a plurality of base memory arrays at a first process node in a memory wafer using a memory photomask set, wherein each of the base memory arrays is surrounded by a plurality of scribe lines;
forming a plurality of control chips at a second process node in a control wafer using a control photomask set, wherein the first process node is more advanced than the second process node, and each of the control chips is configured to control an operation of a corresponding memory chip comprising at least two base memory arrays;
bonding the memory wafer with the control wafer together to form a bonded wafer, wherein each control chip is bonded with the corresponding memory chip; and
cutting the bonded wafer through a subset of, but not all of the scribe lines to form a plurality of chips with integrated memory, wherein each chip with integrated memory comprises a scribe line that was not cut.

2. The method of claim 1, wherein each of the base memory arrays comprises a same amount of memory capacity.

3. The method of claim 1, wherein at least some of the scribe lines comprise an alignment mark or an overlay mark, and the method further comprises bonding the memory wafer with the control wafer in accordance with the alignment mark or the overlay mark.

4. The method of claim 3, wherein there is no dummy metal in a portion of the scribe line comprising the alignment mark or overlay mark.

5. The method of claim 3, wherein at least some of the scribe lines comprise a pattern configured to indicate whether the scribe line is to be cut, and the method further comprises cutting the bonded wafer in accordance with the pattern.

6. The method of claim 1, wherein the control chip is selected from a group consisting of a microcontroller unit (MCU), a power management integrated circuit (PMIC), a display driver integrated circuit (DDIC), and an application-specific integrated circuit (ASIC).

7. The method of claim 1, wherein the control chip comprises a control circuit, wherein the control circuit comprises a multiplexer configured to control a source line or a bit line for a memory cell in the memory chip.

8. The method of claim 7, wherein the memory chip does not comprise a multiplexer configured to control a source line or a bit line for a memory cell in the memory chip.

9. The method of claim 8, wherein the memory chip does not comprise a decoder configured to control a word line for a memory cell in the memory chip.

10. The method of claim 1, wherein a gate length of a transistor in the memory chip is smaller than a gate length of a transistor in the control chip.

11. The method of claim 1, wherein the memory chip comprises only one type of transistors, and the control chip comprises a plurality of types of transistors.

12. The method of claim 11, wherein the memory chip comprises only NMOS transistors.

13. The method of claim 11, wherein the memory chip comprises only PMOS transistors.

14. The method of claim 7, wherein each memory cell comprises a memory element formed above a substrate.

15. The method of claim 14, wherein the memory element is selected from a group consisting of:
a Resistive Random Access Memory (RRAM);
a Conductive-Bridge Random Access Memory (CBRAM);
a Magnetic Random Access Memory (MRAM);
a Ferroelectric Random Access Memory (FeRAM); and
a Phase Change Random Access Memory (PCRAM).

16. The method of claim 7, wherein each memory cell comprises a resistive memory element formed above a substrate.

17. The method of claim 16, wherein the memory cell comprises:
an access transistor formed on the substrate;
a contact;
a first metal layer;
a bottom electrode;
the resistive memory element;
a first via; and
a second metal layer,
wherein the contact is disposed between a terminal of the access transistor and the first metal layer, the bottom electrode is disposed between the first metal layer and the resistive memory element, the first via is disposed between the resistive memory element and the second metal layer.

18. The method of claim 16, wherein a top surface of the memory chip comprises a plurality of first conductive pads and a first insulating region, and a top surface of the control chip comprises a plurality of second conductive pads and a second insulating region.

19. The method of claim 18, wherein a first conductive pad is bonded to a second conductive pad, and the first insulating region is bonded to the second insulating region.

20. The method of claim 18, wherein the plurality of first conductive pads are connected to a second metal layer in the memory chip by a plurality of memory chip vias, and a plurality of second conductive pads are connected to a second metal layer in the control chip by a plurality of control chip vias, wherein the plurality of memory chip vias comprise a same length.

21. The method of claim 1, further comprising:
forming a plurality of base memory arrays at the first process node in a second memory wafer using the memory photomask set, wherein each of the base memory arrays is surrounded by a plurality of second scribe lines;
forming a plurality of second control chips at the second process node in a second control wafer using a second control photomask set different from the control photomask set, and each of the second control chips is configured to control an operation of a corresponding second memory chip comprising at least two base memory arrays;
bonding the second memory wafer with the second control wafer together to form a second bonded wafer, wherein each second control chip is bonded with the corresponding second memory chip; and
cutting the second bonded wafer through a subset of, but not all of the second scribe lines to form a plurality of second chips with integrated memory, wherein each second chip with integrated memory comprises a second scribe line that was not cut.

22. The method of claim 21, wherein the memory chip and the second memory chip comprise different numbers of base memory arrays.

23. A chip with integrated memory, comprising:
a memory chip formed at a first process node, wherein the memory chip comprises at least two base memory arrays, wherein each of the base memory arrays is separated from another base memory array by at least a scribe line; and
a control chip formed at a second process node, wherein the first process node is more advanced than the second process node, and the control chip is configured to control an operation of the memory chip,
wherein a top surface of the memory chip comprises a plurality of first conductive pads and a first insulating region, a top surface of the control chip comprises a plurality of second conductive pads and a second insulating region, the first conductive pad is bonded to a second conductive pad, and the first insulating region is bonded to the second insulating region.

24. The chip of claim 23, wherein each of the base memory arrays comprises a same amount of memory capacity.
